(19) United States
(12) Patent Application Publication
(10) Pub. No.: US 2003/0025519 A1
(43) Pub. Date: Feb. 6, 2003

(54) Inspection apparatus and method for test ambient and test mode circuit on integrated circuit chip

(76) Inventor: Cheng-Ju Hsieh, Hsinchu (TW)

Correspondence Address: CHARLES C. H. WU & ASSOCIATES, 7700 IRVINE CENTER DRIVE, Suite 710, Irvine, CA, 92618-3043, US

(21) Appl. No.: 09/932,757

(22) Filed: Aug. 16, 2001

(30) Foreign Application Priority Data
Aug. 6, 2001 (TW) 90119109

(51) Int. Cl. G01R 31/26

(52) U.S. Cl. 324/765

(57) ABSTRACT

An inspection apparatus and method for test mode circuit and test ambient on an integrated circuit chip. The integrated circuit chip has an input pin, an output pin and a function circuit. The inspection apparatus has a test mode circuit and a test pattern generator. The test mode circuit is built in the integrated circuit chip to test the function circuit. The test pattern generator is coupled to the input pin to receive a test signal. According to the operation of the test mode circuit, an output signal is output from the output pin. According to the output signal, whether the test mode circuit and the test ambient are correct is determined. Thus, when problems occur while testing chips, a lot of time of analysis is saved. Whether the problems occur from the function circuit, the test mode circuit or the test ambient set up is realized.

### CROSS-REFERENCE TO RELATED APPLICATION

This application claims the priority benefit of Taiwan application serial no. 90119109, filed Aug. 6, 2001.

### BACKGROUND OF THE INVENTION

1. Field of Invention

The invention relates an inspection apparatus and method for a test mode circuit.

More particularly, the invention relates to an inspection apparatus and method for a test mode circuit on an integrated circuit.

2. Related Art

As integrated circuit (IC) fabrication techniques continuously advance, integrated circuits are becoming smaller and smaller and more and more powerful. With the trend of system on chip (SOC), many integrated circuits are integrated into a single chip. To test whether the integrated circuit functions normally, specific test mode circuits are designed while designing the chip to test whether the function circuit of the integrated circuits works normally.

The function circuit of the system on chip can be an intellectually property (IP) circuit such as a dynamic random access memory (DRAM), static random access memory (SRAM) and control circuit capture logic circuit.

With the trend of system on chip, the number of the function circuits in an integrated circuit is getting larger and more complex. To obtain correct operation of the integrated circuit, various function circuits require different test mode circuits to ensure that the function circuits operate normally. However, as the test mode circuits are designed as desired for each individual chip, there is no standard for the design. Since the system on chip has many pins, plus different function circuits are integrated, the test method is complicated. To appropriately configure the logics of the pins to test the function circuit by the test mode circuits is complicated.

### SUMMARY OF THE INVENTION

The invention provides an inspection apparatus of a test mode circuit on an integrated circuit and a test ambient. The integrated circuit chip comprises at least an input pin, an output pin and a function circuit. The investigation apparatus comprises a test mode circuit and a test pattern generator. The test mode circuit is built in the integrated circuit chip to test the function circuit. The test pattern generator is coupled to the input pin to receive a test signal. According to the operation of the test mode circuit, an output signal is output from the output pin.

The above function circuit comprises an intellectual property circuit.

The invention further provides an inspection apparatus of a test mode circuit and a test ambient on an integrated circuit chip to improve the problems occurring in the conventional structure. The integrated circuit chip comprises a plurality of input pins, output pins and function circuits. The investigation apparatus includes a plurality of test mode circuits and a plurality of test pattern generators. The test mode circuits are built in the integrated circuit chip to test each of the function circuits. Each of the test pattern generators is coupled to the corresponding input and output pins to receive a test signal, and to output an output signal according to the operation of each of the test mode circuits.

The above function circuits include intellectual property circuits.

The invention further provides a chip with a test mode circuit and a test ambient to resolve the problems occurring in the conventional structure. The chip has an input pin to receive a test signal and an output pin to output an output signal. The chip further includes a function circuit, a test mode circuit, and a test pattern generator. The function circuit is built in the chip. The test mode circuit is built in the chip to test the function circuit. The test pattern generator is coupled between the input and output pins to receive the test signal and output an output signal according to operation of the test mode circuit.

The above function circuit includes an intellectual property circuit.

The invention provides an investigation method of a test mode circuit and a test ambient on an integrated circuit chip. Under a test ambient, a test pattern generator is used to inspect the test mode circuit to improve the conventional problems. The test pattern generator enters a test mode, and a predetermined input signal is input from the input terminal of the test pattern generator. Whether an output signal of the output terminal of the test pattern generator is the predetermined output signal is determined. If it is, the test mode circuit and the test ambient are correct. If not, the test mode circuit and the test ambient are incorrect.

The above method further comprises a step of setting the test ambient.

### BRIEF DESCRIPTION OF THE SEVERAL VIEWS OF THE DRAWING

These, as well as other features of the present invention, will become more apparent upon reference to the drawings, wherein:

FIG. 1 shows a block diagram of an inspection apparatus for a test mode circuit and a test ambient on an integrated circuit chip;

FIG. 2 shows the signal diagram of the test pattern generator as illustrated in FIG. 1;

FIG. 3 shows the block diagram of another embodiment of the inspection apparatus;

FIG. 4 shows the signal diagram of the test pattern generator as illustrated in FIG. 3; and

FIG. 5 shows a process flow of the inspection method for test mode circuit and test ambient of the integrated circuit chip according to the invention.

### DETAILED DESCRIPTION OF THE PRESENT EMBODIMENT

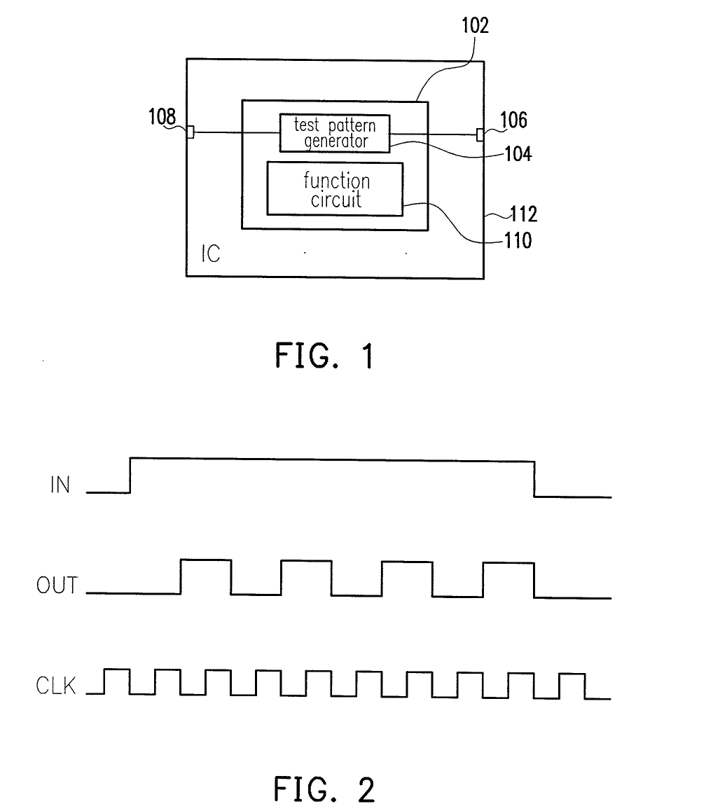

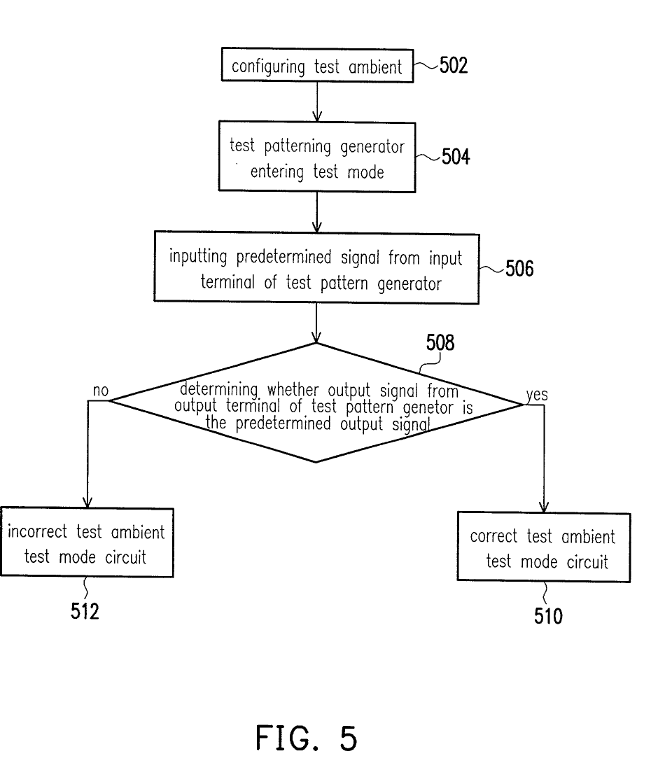

FIG. 1 shows a block diagram of an inspection apparatus for a test mode circuit and a test ambient on an integrated circuit. Referring to FIG. 1 and FIG. 5, a process flow of the inspection method of the test mode circuit and test ambient on the integrated circuit chip according to the invention is shown. The integrated circuit chip has at least an input pin 106, an output pin 108 and a function circuit 110. The inspection apparatus comprises a test mode circuit 102 and a test pattern generator 104. The test mode circuit 102 is built in the integrated circuit chip 112 to test the function circuit 110. The test pattern generator 104 is coupled to the input pin 106 to receive a test signal, and to output an output signal from the output pin 108 according to operation of the test mode circuit 102. In the embodiment, the function circuit includes an intellectual property circuit such as a DRAM, and SRAM. The test pattern generator 104 includes a simple logic circuit such as an assemble logic circuit or sequential logic circuit designed according to specific test ambient.

According to the test mode circuit, the test pattern generator performs an operation according to the test mode circuit 102. Thus, after a test signal is input from the input pin 106, the output signal of the test pattern generator 104 is expected to be identical as predetermined when the test mode circuit 102 works normally. In contrast, if the test mode circuit fails to operate normally after the test signal input from the input pin 106, the output signal of the test pattern generator is different from the predetermined one. Whether the test mode circuit 102 operates normally can thus be determined.

Compared to the prior art that requires a lot of time for analysis when chip testing problems occur, whether the problem occurs from the function circuit or the test mode circuit can be easily determined. In the invention, the factor of whether the test mode circuit 102 operates normally is excluded before performing the test. The user can concentrate on the internal tested circuits. If the test mode circuit 102 fails to function normally, a debug step is performed on the test mode circuit 102 first.

FIG. 5 shows a process flow of the investigation method for a test mode circuit and test ambient on an integrated circuit chip. As shown in FIG. 5, before testing the chip, the required ambient parameters are set up in step 502. The test mode circuit 102 is activated to have the test pattern generator 104 and the function circuit under the same test mode in step 504. A predetermined input signal is input from the input pin 106 to generate an output signal from the test pattern generator 104 in step 506. It is to be noted that the test mode circuit 102 is the test circuit for testing the function circuit 110. That is, the test pattern generator 104 and the function circuit 110 share the same test mode circuit, such that these two can perform tests under the same test mode. An output signal is output from the output pin 108 from the test pattern generator 104. The output signal is observed in step 508.

FIG. 2 shows the signal diagram of the test pattern generator illustrated in FIG. 1. IN is the input signal of the test pattern generator 104, while OUT is the output signal thereof. CLK indicates the operation clock. The test pattern generator 104 is assumed under a test mode, and the test mode circuit 102 and the test ambient are configured under a normal condition.

Therefore, if an input signal such as IN in FIG. 2 is input from the input pin 106, the test pattern generator 104 generates a predetermined output signal such as OUT in FIG. 2 output from the output pin 108. Therefore, if the output signal is identical to the predetermined output signal, it is easy to realize that there are no problems of the test mode circuit 102 and the test ambient configuration in step 510. When problems occur to the function circuit 110 which is tested or operated normally, the occurrence from the test mode circuit 102 and test ambient configuration can be excluded first to save a lot of analysis time. If the output signal is different from the predetermined one, it indicates that one of the test mode circuit 102 and the test ambient is faulty, or both of them are faulty (step 512). Before testing the function circuit 110, the problems occurring to the test mode circuit 102 and the test ambient configuration can be resolved first. Thus, if problems occur when the IC is tested, the problems from the test mode circuit 102 and the test ambient configuration can be excluded.

The above input pin 106 and output pin 108 includes the pins of the IC. Or alternatively, another set of pins can be provided to the IC for use of the test pattern generator 104.

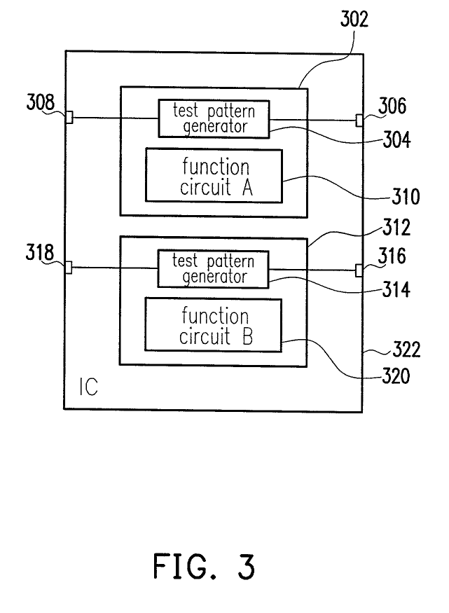

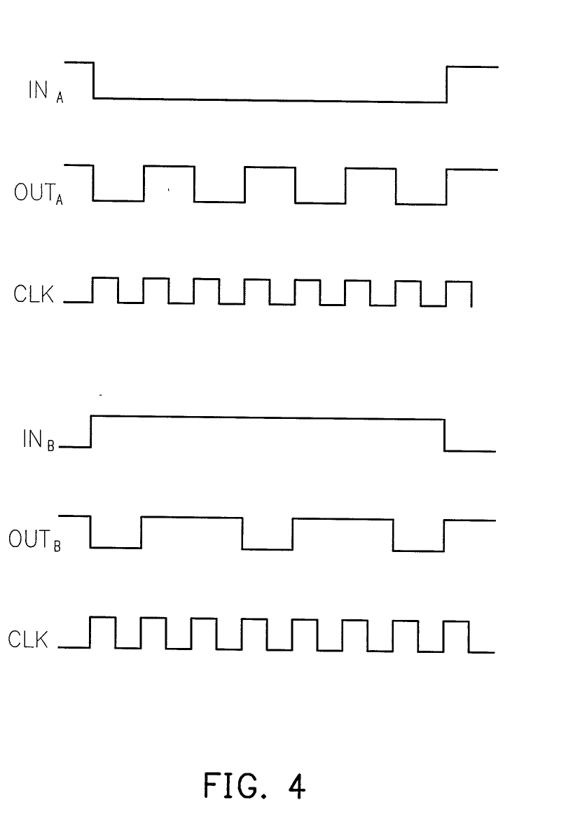

It is known to one of ordinary skilled in the art that when there is more than one function circuit in the IC, different test mode circuits have different corresponding test pattern generators as shown in FIG. 3.

In addition, the input signal and the predetermined output signal are variable according to the designs of the test mode circuit 102 and the test pattern generator 104. The input signal and output signal do not have to be the same as those illustrated in FIG. 2. Referring to FIG. 4, the signal diagram of the test pattern generator corresponding to the function circuit is illustrated. Different input signal and output signal may be obtained from different test circuit and test pattern generator.

According to the above, the invention has the advantage of saving time when analyzing the problems occurring during a test. Whether the problems are from the test mode circuit, the test ambient configuration, or the function circuit can be easily determined.

It is to be further understood that various additions, deletions, modifications and alterations may be made to the above-described embodiments without departing from the intended spirit and scope of the present invention. Accordingly, it is intended that all such additions, deletions, modifications and alterations be included within the scope of the following claims.

What is claimed is:

1. An inspection apparatus for a test mode circuit and a test ambient on an integrated circuit chip with at least an input pin, an output pin and a function circuit, the inspection apparatus comprising:
a test mode circuit, built in the integrated circuit chip to test the function circuit; and
a test pattern generator, coupled to the input pin to receive a test signal, and to output an output signal from the output pin according to operation of the test mode circuit.

2. The inspection apparatus of claim 1, wherein the function circuit comprises an intellectual property circuit.

3. An inspection apparatus for a test mode circuit and a test ambient on an integrated circuit chip with a plurality of input pins, a plurality of output pins and a plurality of function circuits, the inspection apparatus comprising:
a plurality of test mode circuits, built in the integrated circuit chip to test the function circuits; and
a plurality of test pattern generators, each of which is coupled to the corresponding input pin and the corresponding output pin to receive a test signal, and to output an output signal from the output pin according to operation of the test mode circuits.

4. The inspection apparatus of claim 3, wherein the function circuit comprises an intellectual property circuit.

5. A chip capable of inspecting a test mode circuit and a test ambient, the chip having an input pin to receive a test signal, and an output pin to output an output signal, the chip comprising:
a function circuit, built in the chip; and
a test pattern generator, coupled between the input pin and the output pin to receive the test signal, and to generate an output signal according to operation of the test mode circuit.

6. The chip of claim 5, wherein the function circuit comprises an intellectual property circuit.

7. A method of inspecting a test mode circuit and a test ambient on an integrated circuit chip, using a test pattern generator to inspect the test mode circuit under the test ambient, the method comprising:
allowing the test pattern generator to enter a test mode;
inputting an input signal from an input terminal of the test pattern generator;
determining whether an output signal output from the output terminal of the test pattern generator is the same as a predetermined output signal; wherein
if the output signal is the same as the predetermined output signal, the test mode circuit and the test ambient are correct; and
if the output signal is different from the predetermined output signal, the test mode circuit and the test ambient are incorrect.

8. The method of claim 7, further comprising a step of configuring the test ambient.
